(19) United States
(12) Patent Application Publication
(10) Pub. No.: US 2016/0349326 A1
(43) Pub. Date: Dec. 1, 2016

(54) DEBUG TRIGGER INTERFACE FOR NON-DEBUG DOMAIN SYSTEM RESET

(71) Applicant: ANALOG DEVICES GLOBAL, Hamilton (BM)

(72) Inventors: Richard F. Grafton, Abington, MA (US); Chad R. Wentworth, Fitchburg, MA (US); Yashwanth Nagaraja, Bangalore (IN)

(73) Assignee: ANALOG DEVICES GLOBAL, Hamilton (BM)

(21) Appl. No.: 14/721,152

(22) Filed: May 26, 2015

(51) Int. Cl. G01R 31/317; G01R 31/3177

(52) U.S. Cl. CPC G01R 31/31705; G01R 31/3177

(57) ABSTRACT

A system, such as a system-on-chip, has a non-debug domain and a debug domain. The debug domain has a debug framework that enables a debugger driven, non-debug domain system reset. The system includes a reset control unit, and a debug trigger mechanism that includes a debug trigger interface (DTI) connected to the reset control unit. The DTI is configured to trigger the reset control unit to reset the non-debug domain. The DTI may further be configured to monitor a status of the non-debug domain system reset.

### TECHNICAL FIELD

The present disclosure relates generally to system-on-chips (SoCs), and more particularly, to debug environments for SoCs.

### BACKGROUND

Debuggers are specialized software (and its associated supporting hardware) that detect and correct any errors (bugs) in a target system, such as a system-on-chip. Debuggers prefer to provide a clean debug session by bringing the target system to a known state. This is best accomplished by resetting the target system's non-debug domain to a known state before beginning a debug session without affecting the target system's debug domain. Although existing non-debug domain system reset mechanisms have been generally adequate for their intended purposes, they have not been entirely satisfactory in all respects.

### BRIEF DESCRIPTION OF DRAWINGS

The present disclosure is best understood from the following detailed description when read with the accompanying figures. It is emphasized that, in accordance with the standard practice in the industry, various features are not drawn to scale and are used for illustration purposes only. In fact, the dimension of the various features may be arbitrarily increased or reduced for clarity of discussion.

FIG. 1 is a schematic block diagram of an exemplary debug environment according to various aspects of the present disclosure.

FIG. 2 is a schematic block diagram of an exemplary debug trigger interface system reset mechanism, which can be implemented in debug environment of FIG. 1, according to various aspects of the present disclosure.

FIG. 3 is a flowchart of exemplary method that can be implemented for providing a non-debug domain reset in a debug environment, such as debug environment of FIG. 1, according to various aspects of the present disclosure.

FIG. 4 is a flowchart of an exemplary method that can be implemented for providing a non-debug domain system reset in a debug environment, such as debug environment of FIG. 1, according to various aspects of the present disclosure.

### OVERVIEW OF EXAMPLE EMBODIMENTS

A system, such as a system-on-chip, has a non-debug domain and a debug domain. The debug domain has a debug framework that enables a debugger driven, non-debug domain system reset. The system includes a reset control unit, and a debug trigger mechanism that includes a debug trigger interface (DTI) connected to the reset control unit. The DTI is configured to trigger the reset control unit to reset the non-debug domain. The DTI may be further configured to monitor a status of the non-debug domain system reset.

In some implementations, the DTI has a trigger output connected to a non-debug domain system reset request of the reset control unit, and a trigger input connected to a non-debug domain system reset status of the reset control unit. The trigger output may be connected to the non-debug domain system reset request via an inverter, and the trigger input may be connected to the non-debug domain system reset status via an inverter. The DTI can include an application trigger register configured to cause the DTI to issue (assert) a non-debug domain system reset request to the reset control unit. The DTI can further include an application trigger in status register configured to indicate a status of the non-debug domain system reset. A debugger connected to the system use the application trigger register and application trigger in status register for debugger non-debug system reset assertion operations. For example, the debugger can program application trigger register to a state that causes the DTI to issue (assert) the non-debug domain system reset request to the reset control unit. The debugger can also monitor the application trigger in status register to determine the status of the non-debug domain system reset.

### DETAILED DESCRIPTION OF EXAMPLE EMBODIMENTS

Debuggers are specialized software (and its associated supporting hardware) that detect and correct any errors (bugs) in a target system. Debuggers prefer to provide a clean debug session by bringing all intellectual property (IP) blocks of the target system, such as a system-on-chip (SoC), to a known state. This is best accomplished by resetting the target system's non-debug domain (for example, all non-debug IP blocks) to a known state before beginning a debug session without affecting the target system's debug domain, such as any debug logic that has already been initialized to perform debug operations.

Debuggers typically interact with a debug framework, such as ARM® CoreSight™ debug and trace framework, associated with the target system to accomplish desired debug operations. Currently, SoC debug frameworks do not support debuggers directly providing a non-debug domain system reset. For example, a SoC configured with ARM® CoreSight™ debug and trace framework may include a debug access port that has direct control/status signaling and handshake mechanisms for enabling debug domain power-up, non-debug domain power-up, and debug domain reset, but not non-debug domain system reset. In some configurations, an ARM® CoreSight™ debug and trace system model requires a core processor of the SoC to perform a specific process that enables a debugger to indirectly initiate a non-debug domain system reset. However, indirect non-debug domain system resets can cause problems since the operations associated with indirect system resets typically involve components that are affected by the system reset, such that the operations cannot be completed without protocol violations and/or errors.

To address such issues, the following disclosure proposes a target system debug framework configured with a non-debug domain system reset mechanism that enables a debugger to bring a non-debug domain of the target system to a known state. The debug framework leverages a debug trigger interface (such as a cross-trigger interface provided by ARM® CoreSight™ debug and trace framework) to create control/status signaling and handshake mechanisms for enabling the non-debug domain system reset. Different embodiments may have different advantages, and no particular advantage is necessarily required of any of the embodiments described herein.

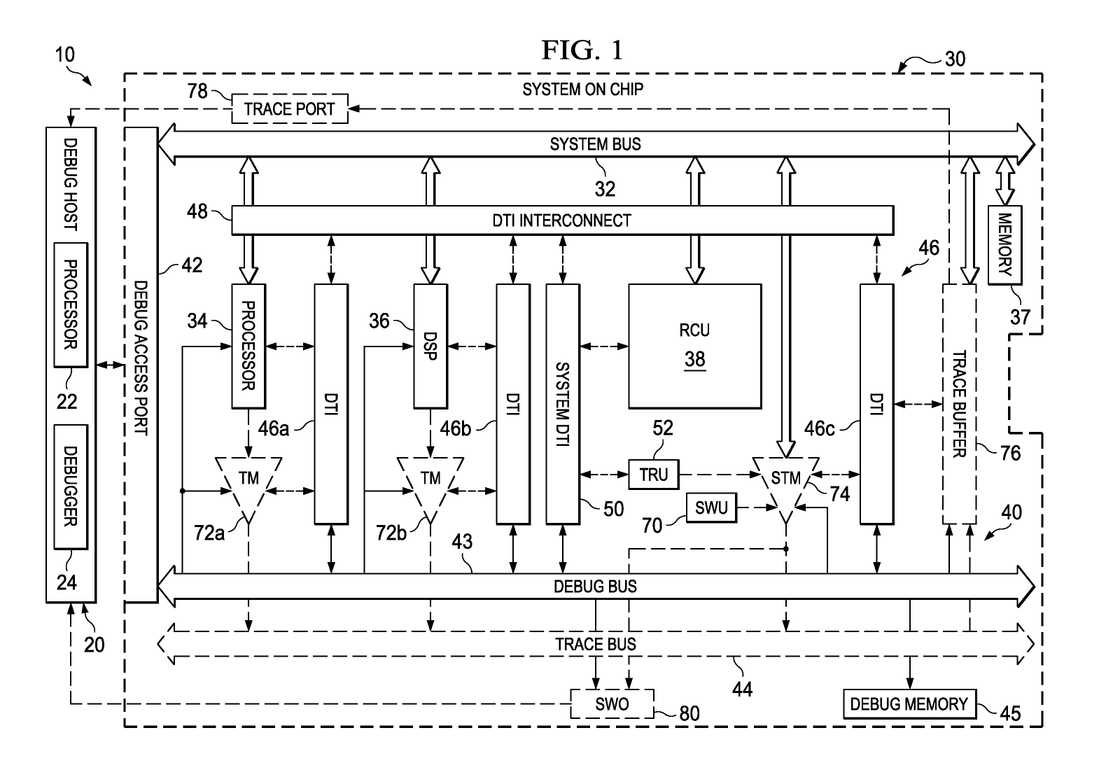

FIG. 1 is a schematic block diagram of an exemplary debug environment 10 for performing debugging and tracing operations according to various aspects of the present disclosure. As described below, debug environment 10 provides a debugger driven, non-debug domain system reset. FIG. 1 has been simplified for the sake of clarity to better understand the inventive concepts of the present disclosure. Additional features can be added in debug environment 10, and some of the features described can be replaced or eliminated in debug environment 10.

In FIG. 1, a debug host system 20 (also referred to as a debug host or an external debugger) includes a processor 22 that can execute software, such as a debugger 24, for debugging and tracing various components of a target system connected thereto. Debugger 24 can communicate with a non-debug domain and a debug domain associated with the target system to facilitate the debugging and tracing operations. In various implementations, debug host system 20 sends various debug and trace requests to a debug and trace system associated with the target system, which can execute such requests and send information related to such requests to debug host system 20.

For purposes of the following discussion, the target system is depicted as a system-on-chip (SOC) 30, where components of the target system are integrated in a single chip. SoC 30 includes a system interconnect 32 that interconnects various components of SoC 30. For example, SoC 30 may include a processor 34, a processor 36, a memory 37, and various other components connected to system interconnect 32, such that processor 34, processor 36, memory 37 and the various other components can communicate with one another via system interconnect 32. In the depicted embodiment, processor 36 is a digital signal processor (DSP). The various components of SoC 30 can provide various systems, including but not limited to, memory systems, video/graphics systems, audio systems, power management systems, security systems, input/output systems, wired/wireless connectivity systems, or a combination thereof.

A reset control unit (RCU) unit 38 is configured to reset SoC 30 and/or various components of SoC 30, such as processor 34 and/or processor 36, upon a hardware-triggered event and/or a software-triggered event. Reset control unit 38 can control how SoC 30, and its various components, enters and exit reset, including a hardware reset, a system reset, a processor only reset, and/or other type of reset. Reset generally refers to a known, initial state of SoC 30 and/or various components of SoC 30, and system reset (also referred to as a non-debug domain system reset) generally refers to setting all components of SoC 30, except reset control unit 38 and a debug domain of SoC 30, to their associated default state. To initiate a system reset, reset control unit 38 can communicate reset signaling via system interconnect 32 to processor 34, processor 36, and/or other components of SoC 30. In various implementations, reset control unit 38 includes a reset control for triggering a non-debug domain system reset. The reset control may be implemented as a control register that includes a bit (or bits) that control asserting/deasserting a non-debug domain system reset. As described further below, debug environment 10 is configured such that debugger 24 can communicate a non-debug domain system reset request to reset control unit 38, and thus debugger 24 can initiate a non-debug domain system reset of SoC 30. The non-debug domain system reset can set all (or portions, in some embodiments) of the non-debug domain of SoC 30 to a known, default state without affecting the debug domain.

A debug and trace system 40 of SoC 30 enables debug host system 20 to access and control various components of SoC 30 to accomplish debugging and tracing of various components of SoC 30. In various implementations, debug and trace system 40 can be based on ARM® CoreSight™ debug and trace framework, which is modified as described herein to achieve a non-debug domain system reset from a debug domain of SoC 30. Debug and trace system 40 includes a debug access port (DAP) 42 that provides access to SoC 30. In various implementations, debug access port 42 may be implemented with a joint test action group (JTAG) debug port, a serial wire debug (SWD) port, other suitable debug port, or a combination thereof. Debug host system 20 (particularly, debugger 24) can connect to and communicate with SoC 30 through debug access port 42 to perform debugging and tracing operations on SoC 30, and debug and trace system 40 can communicate debug information, trace information, and/or other information to debug host system 20 through debug access port 42. For example, in the depicted embodiment, debug host system 20 can access system resources (such as processor 34, processor 36, and/or system memory 37) through system bus 32 connected to debug access port 42; debug host system 20 can access debug components and trace components of SoC 30 (making up debug and trace system 40) through a debug bus 43 connected to debug access port 42; and debug host system 20 can access trace data and trace information through a trace bus 44 connected to debug access port 42. Debug bus 43 is configured to connect debug and trace components of SoC 30, facilitating transfer of debug data and debug information across SoC 30. Trace bus 44 is configured to connect various trace components of SoC 30, facilitating transfer of trace data and trace information across SoC 30. In various implementations, debug bus 43 can be an Advanced Peripheral Bus (APB) or other suitable debug bus, and trace bus 44 can be an Advanced Trace Bus (ATB) or other suitable trace bus. In various implementations, debug and trace system 40 can include a debug memory 45 that stores information about each debug component and/or trace component connected to debug bus 43. For example, a read only memory (ROM) table can store a location of each debug component and/or trace component (such as processor 34, processor 36, debug access port 42, and other debug and/or trace components) connected to debug bus 43.

Debug and trace system 40 further includes a debug trigger mechanism (such as an embedded cross trigger provided by ARM® CoreSight™ debug and trace framework) for communicating debug events across SoC 30. For example, processor 34, processor 36, and various other components of debug and trace system 40 can communicate debug events to one another via the debug trigger mechanism. Debug events can include instruction breakpoints, data breakpoints, watchpoints, and other messaging associated with debugging. In various implementations, debug trigger mechanism enables communicating debug events to various endpoints of SoC 30 for halting processor cores and/or triggering trace capture. Debug trigger mechanism includes various debug trigger interfaces (DTIs) 46 (such as cross trigger interfaces provided by ARM® CoreSight™ debug and trace framework) and a debug trigger interface interconnect 48 (such as a cross trigger matrix provided by ARM® CoreSight™ debug and trace framework) that interconnects the various DTIs 46. In FIG. 1, a DTI 46a interconnects processor 34 with DTI interconnect 48, a DTI 46b interconnects processor 36 with DTI interconnect 48, and a DTI 46c interconnects various trace components of debug and trace system 40 with DTI interconnect 48. Each DTI enables its associated SoC component (such as processor 34, processor 36, debug component, or trace component) to broadcast and respond to debug events (triggers) on DTI interconnect 48, where DTI 48 broadcasts debug events from one DTI to other DTIs. For example, each DTI maps trigger event inputs received from its associated system (such as processor 34 for DTI 46a) onto channels associated with DTI interconnect 48, and maps channel inputs received from DTI interconnect 48 to trigger event outputs for its associated system. Each DTI can also include associated DTI registers (not shown), which debugger 24 can use to generate internal trigger event inputs for DTIs 46, thus facilitating software-triggered events.

Typically, debug and trace system 40 implements debug trigger interfaces (such as DTI 46a, DTI 46b, and DTI 46c) and their associated signaling mechanisms for communicating debug events and controlling debug actions corresponding to such debug events. The present disclosure recognizes that, since a debug trigger interface is connected to a debug domain reset only and thus is not affected by any non-debug domain system reset, the debug trigger interface and its associated signaling mechanisms can be configured to provide a non-debug domain system reset, which is not a typical debug event or a typical debug action. In particular, debug environment 10 can leverage a debug trigger interface and its associated signaling to enable debugger 24 to request and monitor a non-debug domain system reset of a target system, such as SoC 30. For example, in FIG. 1, debug trigger mechanism further includes a system DTI 50 connected to reset control unit 38, where system DTI 50 is configured to request and monitor a status of a non-debug domain system reset, as described further below.

In many respects, system DTI 50 is similar to DTIs 46. System DTI 50 enables its associated system (such as reset control unit 38 or other component of SoC 30 (for example, a trigger routing unit 52)) to broadcast and respond to debug events on DTI interconnect 48. For example, similar to DTIs 46, system DTI 50 can map trigger event inputs received from reset control unit 38 and/or trigger routing unit 52 onto channels associated with DTI interconnect 48, and map channel inputs received from DTI interconnect 48 to trigger event outputs for reset control unit 38 and/or trigger routing unit 52. System DTI 50 further includes associated system DTI registers (not shown in FIG. 1) that allow debugger 24 to generate internal trigger event inputs for system DTI 50. In various implementations, debugger 24 can configure system DTI registers via debug bus 43 to provide a software-triggered non-debug domain system reset, utilizing system DTI 50 to request that reset control unit 38 perform a system reset and thereafter monitor a status of the non-debug domain system reset based on system reset status signaling received from reset control unit 38.

Where SoC 30 includes a system master halt/restart control (not shown) for triggering a system halt/system restart for system masters (such as processor 34, processor 36, a DMA controller, etc.) and a system peripheral halt/restart control (not shown) for triggering a system halt/system restart for system peripherals (such as a general-purpose timer, a watchdog timer, a pulse-width modulator, etc.), system DTI 50 can further be connected to system master halt/restart control and system peripheral halt/restart control, allowing system DTI 50 to initiate system master halt/restart and system peripheral halt/restart. System master halt/restart control and system peripheral halt/restart control may be implemented as control registers that respectively include a bit (or bits) that controls asserting/deasserting a system master halt/restart and a bit (or bits) that controls asserting/deasserting a system peripheral halt/restart. In some implementations, debugger 24 can configure system DTI registers so that system DTI 50 can trigger system master halt/restart and/or system peripheral halt/restart. In some implementations, debugger 24 can monitor system DTI registers for a status of system master halt/restart and/or a status of system peripheral halt/restart.

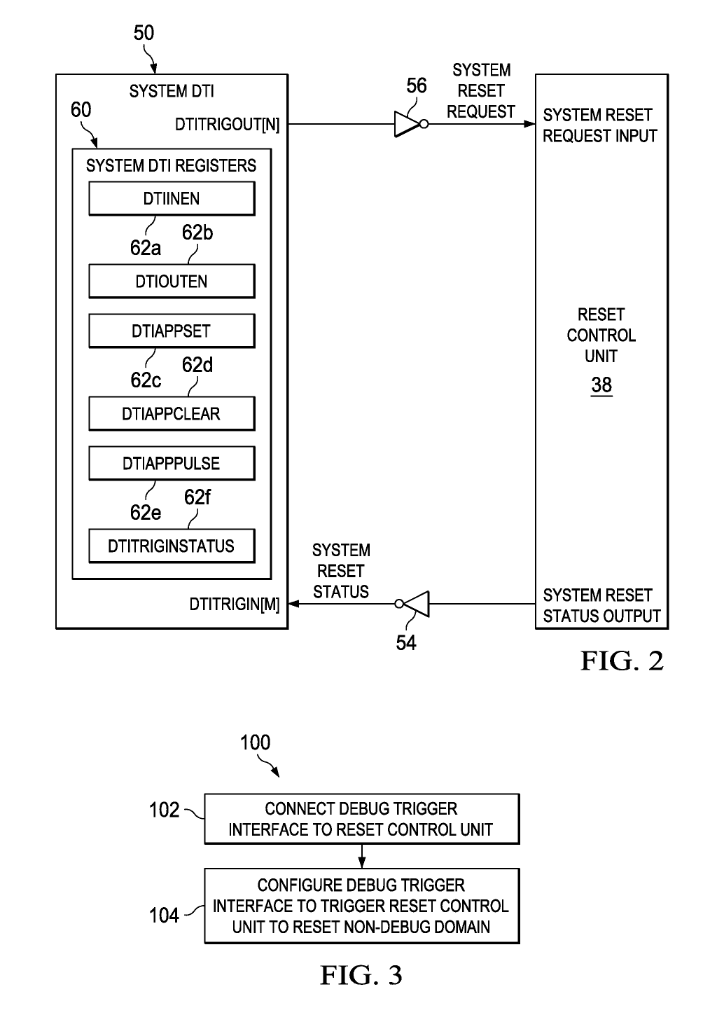

Turning to FIG. 2, FIG. 2 is a schematic block diagram of an exemplary debug trigger interface system reset mechanism, which can be implemented in debug environment 10 of FIG. 1, according to various aspects of the present disclosure. In FIG. 2, the debug trigger interface system reset mechanism leverages system DTI 50 and its associated signaling to enable debugger 24 to request and monitor a non-debug domain system reset. Leveraging the signaling from system DTI 50 provides a seamless solution for initiating a system reset directly from debug logic to reset control unit 38. In some implementations, system DTI 50 is an ARM® CoreSight™ cross-trigger interface (CTI), where the ARM® CoreSight™ CTI's signaling (including ARM® CoreSight™ CTI registers) is leveraged to initiate non-debug domain system reset. FIG. 2 has been simplified for the sake of clarity to better understand the inventive concepts of the present disclosure. Additional features can be added in the debug trigger interface system reset mechanism, and some of the features described can be replaced or eliminated in other embodiments of the debug trigger interface system reset mechanism.

System DTI 50 includes a trigger in interface configured to receive various trigger inputs from reset control unit 38 and/or other associated system (such as trigger routing unit 52), and a trigger out interface configured to send various trigger event outputs to reset control unit 38 and/or other associated system. For example, system DTI 50 has m trigger inputs and n trigger outputs, where m is a total number of trigger inputs associated with trigger in interface, and n is a total number of trigger outputs associated with trigger out interface. In various implementations, system DTI 50 has a trigger input and a trigger output configured for non-domain system reset signaling. In FIG. 2, a trigger input M (DTITRIGIN[M]) is connected to system reset status signaling of reset control unit 38 (M being an integer from one to m), such that system DTI 50 can receive a system reset status from reset control unit 38, and a trigger output N (DTITRIGOUT[N]) is connected to system reset request signaling of reset control unit 38 (N being an integer from one to n), such that system DTI 50 can request that reset control unit 38 initiate (assert) a non-debug domain system reset. Debugger 24 can issue a non-debug domain system reset request by configuring DTI 50 to issue (ssert) a non-debug domain system reset request via trigger output N (DTITRIGOUT[N]) to reset control unit 38, and can further observe a status of the non-debug domain system reset by monitoring a non-debug domain system reset status received by DTI 50 via trigger input M (DTITRIGIN[M]) from reset control unit 38. In some implementations, trigger input M (DTITRIGIN[M]) is connected to a system reset status output of reset control unit 38 via an inverter 54, and trigger output N (DTITRIGOUT[N]) is connected to a system reset request input via an inverter 56. For example, inverting non-debug domain system reset signaling can be implemented when reset control unit 38 uses active low inputs for system reset purposes, such as system reset request logic.

System DTI 50 further includes a system DTI register set 60, which debugger 24 can configure to generate system reset signaling and observe system reset status signaling. Each system DTI register may be a 32-bit register, though the present disclosure contemplates any size system DTI registers. In the depicted embodiment, system DTI register set 60 includes a DTI Trigger to Channel Enable Register (DTIINEN) 62a, a DTI Channel to Trigger Enable Register (DTIOUTEN) 62b, a DTI Application Trigger Set Register (DTIAPPSET) 62c, a DTI Application Trigger Clear Register (DTIAPPCLEAR) 62d, a DTI Trigger In Status Register (DTITRIGINSTATUS) 62e, a DTI Application Pulse Register (DTIAPPPULSE) 62f, and/or other various system DTI registers. In some implementations, system DTI register set 60 is an ARM® CoreSight™ cross-trigger interface (CTI) register set that includes a CTI Trigger to Channel Enable register, CTI Channel to Trigger Enable register, CTI Application Trigger Clear register, CTI Trigger In Status register, CTI Application Trigger Set register, CTI Application Pulse register, and/or other CTI register. As described below, debugger 24 can issue a non-debug domain system reset request by configuring (for example, writing to) DTI Application Trigger Set Register 62c. Further, debugger 24 can observe a status of the non-debug domain system reset by monitoring (for example, reading) DTI Trigger In Status Register 62e. In the depicted embodiment, reset control unit 38 implements active low states for non-debug domain system reset purposes. Accordingly, by inverting a trigger output signal from trigger output N and connecting the inverted trigger output signal to a system reset request of reset control unit 38, debugger 24 can issue a non-debug domain system reset request by configuring (for example, writing to) DTI Application Trigger Set Register 62c. Further, by inverting a system reset signal from reset control unit 38 and connecting the inverted system reset signal to trigger input N, debugger 24 can observe a status of the non-debug domain system reset by monitoring (for example, reading) DTI Trigger In Status Register 62e.

DTI Trigger to Channel Enable Register 62a is a read/write register that enables signaling of an event on a channel of DTI interconnect 48 when reset control unit 38 or other associated system (such as trigger routing unit 52) issues a trigger event input to system DTI 50. Each trigger input of system DTI 50 may have an associated DTI Trigger to Channel Enable Register 62a. For example, system DTI register set 60 may include m DTI Trigger to Channel Enable Registers 62a. DTI Trigger to Channel Enable Register 62a includes an enable trigger in bit (or bits) associated with each channel of DTI interconnect 48, which can be set to a first state, such as a LOW state (for example, a digital 0) or a second state, such as a HIGH state (for example, a digital 1). For a given channel, an enable trigger in bit set to the first state disables a trigger input from generating an event on the channel; and the enable trigger in bit set to the second state enables the trigger input to generate an event on the channel. In the present example, DTI Trigger to Channel Enable Register 62a may be associated with trigger input M (DTITRIGIN[M]). Since trigger input M is designated for receiving non-debug domain system reset status signaling from reset control unit 38, each enable trigger in bit can be set to the first state (for example, a digital 0) to ensure that a channel event is not generated when system DTI 50 receives a system reset status signal on trigger input M from reset control unit 38. Accordingly, for non-debug domain system reset purposes, system DTI 50 includes a trigger input (here, trigger input M) that will not be mapped to any channel.

DTI Channel to Trigger Enable Register (DTIOUTEN) 62b is a read/write register that defines which channel(s) of DTI interconnect 48 can generate a trigger output. Generally, DTI Channel to Trigger Enable Register 62b maps application triggers, such as software-triggered events from debugger 24, to trigger outputs of system DTI 50. Each trigger output from system DTI 50 may have an associated DTI Channel to Trigger Enable Register 62b. For example, system DTI register set 60 may include n DTI Channel to Trigger Enable Registers 62b. DTI Channel to Trigger Enable Register 62b includes an enable trigger out bit (or bits) associated with each channel of DTI interconnect 48, which can be set to the first state (LOW state) or the second state (HIGH state). For a given channel, an enable trigger out bit set to the first state disables a channel input from being routed to the trigger output; and the enable trigger out bit set to the second state enables routing the channel input to the trigger output. Changing an enable trigger out bit from the first state to the second state enables a channel event for the channel to generate a trigger event on the trigger output. In the present example, DTI Channel to Trigger Enable Register 62b may be associated with trigger output N (DTITRIGOUT[N]), and DTI Channel to Trigger Enable Register 62b may include an enable trigger out bit associated with a channel X of DTI interconnect 48 that is assigned as a system reset request channel. Since trigger output N is designated for sending non-debug domain system reset request signaling to reset control unit 38, an enable trigger out bit associated with channel X may be set to the second state (for example, a digital 1) to ensure that any channel event triggered on channel X by debugger 24 is routed to trigger output N to reset control unit 38. Accordingly, for non-debug domain system reset purposes, system DTI 50 includes a trigger output (here, trigger output N) that will be mapped to a channel (here, channel X) used by debugger 24 for triggering non-debug domain system reset.

DTI Application Trigger Set Register (DTIAPPSET) 62c is a read/write register that enables an application, such as debugger 24, to raise a channel event. DTI Application Trigger Set Register 62c includes an application trigger bit (or bits) associated with each channel of DTI interconnect 48, which can be set to the first state (LOW state) or the second state (HIGH state). For a given channel, debugger 24 can set an application trigger bit to the second state to generate a channel event for the channel. Otherwise, the application trigger bit is set to the first state, indicating that the application trigger for the channel is inactive. In the present example, DTI Application Trigger Set Register 62c may include an application trigger bit associated with channel X of DTI interconnect 48, which has been assigned as the system reset request channel. Accordingly, for non-debug domain system reset purposes, debugger 24 can initiate a non-debug domain system reset by setting the application trigger bit associated with channel X to the second state (for example, a digital 1), causing a system reset channel event to be raised on channel X. Since a channel event on channel X will be routed to trigger output N connected to system reset request input of rest control unit 38 (as a result of how debugger 24 configured DTI Channel to Trigger Enable Register 62b), debugger 24 can issue a non-debug domain system request by writing to DTI Application Trigger Set Register 62c.

DTI Application Trigger Clear Register (DTIAPPCLEAR) 62d is a read/write register that enables an application, such as debugger 24, to clear a channel event. DTI Application Trigger Clear Register 62d includes an application trigger clear bit (or bits) associated with each channel of DTI interconnect 48, which can be set to the first state (LOW state) or the second state (HIGH state). For a given channel, debugger 24 can set an application trigger clear bit to the second state to clear a channel event for the channel. Otherwise, the application trigger clear bit is set to the first state. In the present example, DTI Application Trigger Clear Register 62d may include an application trigger clear bit associated with channel X. Accordingly, for non-debug domain system reset purposes, debugger 24 can clear the non-debug domain system reset by setting the application trigger clear bit associated with channel X to the second state (for example, a digital 1), causing the system reset channel event to be cleared on channel X.

Alternatively, DTI Application Pulse Register (DTIAPPPULSE) 62e can be used for asserting and deasserting non-debug domain system reset. DTI Application Pulse Register 62e is a write only register that enables an application, such as debugger 24, to raise a channel event pulse for some clock period, such as a clock period of debug trigger mechanism. In contrast to DTI Application Trigger Set Register 62c, DTI Application Pulse Register 62e clears itself so that the application, such as debugger 24, does not have to clear the channel event once raised. DTI Application Pulse Register 62e includes an application pulse bit (or bits) associated with each channel of DTI interconnect 48, which can be set to the first state (LOW state) or the second state (HIGH state). For a given channel, debugger 24 can set an application pulse bit to the second state to generate a channel event pulse for the channel for some time, such as a clock period of debug trigger mechanism. Otherwise, the application pulse bit is set to the first state, indicating that the application trigger for the channel is inactive. In the present example, DTI Application Pulse Register 62e may include an application pulse bit associated with channel X of DTI interconnect 48. Accordingly, for non-debug domain system reset purposes, debugger 24 can initiate a non-debug domain system reset by setting the application pulse bit associated with channel X to the second state (for example, a digital 1), causing a system reset channel event pulse to be raised on channel X for a defined time. Since a channel event on channel X will be routed to trigger output N connected to system reset request input of reset control unit 38, debugger 24 can issue a non-debug domain system request by writing to DTI Application Pulse Register 62e, which will automatically be cleared after the defined time.

DTI Trigger In Status Register 62f is a read-only register that includes trigger in status bits that indicate a status of trigger inputs to system DTI 50. DTI Trigger In Status Register 62f can include a trigger in status bit (or bits) associated with each trigger input to system DTI 50. A trigger in status bit is set to the first state (LOW state) when its associated trigger input is inactive, and a second state (HIGH STATE) when its associated trigger input is active. In the present example, DTI Trigger In Status Register 62f can include a trigger in status bit corresponding with trigger input M (DTITRIGIN[M]). Since trigger input M is designated for receiving non-debug domain system reset status signaling from reset control unit 38, debugger 24 can monitor a non-debug domain system reset status by evaluating (for example, reading) a state of the trigger in status bit corresponding with trigger input M.

In an exemplary operation of debug environment 10, when debugger 24 connects (attaches) to SoC 30, debugger 24 can configure a debug domain of SoC 30. For example, debugger 24 can initialize configuration settings for any accessible debug logic of SoC 30. Before performing a debug session, debugger 24 can initiate a non-debug domain system reset that brings SoC 30 to a known state without affecting the debug domain of SoC 30, such as any debug logic that has already been initialized for performing debug operations. As described above, debugger 24 can assign a channel of the SoC's debug trigger mechanism for non-debug domain system reset signaling (such as channel X), map a trigger output of system DTI 50 (such as trigger output N) to the channel assigned for non-debug domain system reset signaling (for example, DTIOUTNEN[N]==′channel X enabled′), and ensure that a trigger input of system DTI 50 (such as trigger input M) is not mapped to any channel (for example, DTIINEN[M]==4′b0). After polling (observing) DTI Trigger In Status Register 62f, specifically the trigger in status bit corresponding with trigger input M, to confirm that a non-debug domain system reset has not been asserted (for example, DTITRIGIN[M]==0), debugger 24 can assert a non-debug domain system reset by writing to DTI Application Trigger Set Register 62c, specifically the application trigger bit associated with channel X (for example, DTIAPPSET[X]==1). This causes a system reset channel event to be raised on channel X, which provides non-debug domain system reset request signaling to reset control unit 38.

Reset control unit 38 can then initiate a non-debug domain system reset upon receiving the non-debug domain system reset request signaling, resetting all endpoints of SoC 30 except for the reset control unit 38 and the debug domain, including any debug logic of the endpoints. Debugger 24 can poll (observe) DTI Trigger In Status Register 62f, specifically the trigger in status bit corresponding with trigger input M, until it indicates that the non-debug domain system reset has been asserted (for example, DTITRIGIN[M]==1). Once debugger 24 confirms that the non-debug domain system reset has been asserted, debugger 24 can clear the non-debug domain system reset request by writing DTI Application Trigger Set Register 62c, specifically the application trigger bit associated with channel X (for example, DTIAPPSET[X]==0). Alternatively, debugger 24 can write to DTI Application Trigger Clear Register 62d, specifically the application trigger bit associated with channel X (for example, DTIAPPCLEAR[X]==1) to deassert the system reset. Debugger 24 can then poll (observe) DTI Trigger In Status Register 62f again, specifically the trigger in status bit corresponding with trigger input M, to ensure that the non-debug domain system reset has been deasserted (for example, DTITRIGIN[M]==1). Debugger 24 then knows that SoC 30 is in a known state, and debugger 24 can perform the debug session.

Returning to FIG. 1, SoC 30 further includes trigger routing unit (TRU) 52, where system DTI 50 is connected to trigger routing unit 52. In various implementations, remaining trigger inputs and/or trigger outputs from system DTI 50, such as trigger inputs and trigger outputs not connected to reset control unit 38, may be connected to trigger routing unit 52. Trigger routing unit 52 can provide system-level sequence control and system-level synchronization for SoC 30 without core intervention, for example, from processor 34 and/or processor 36. In various implementations, trigger routing unit 52 maps trigger masters (trigger generators) to trigger slaves (trigger receivers).

SoC 30 can further include a system watchpoint unit (SWU) 70 configured for transaction monitoring, which can provide debug support. System watchpoint unit 70 can generate events (such as a trace message, a trigger, or an interrupt) based on monitoring transactions at the system slaves. In various implementations, system watchpoint unit 70 uses various watchpoint match groups for transaction monitoring.

To facilitate non-invasive, real-time debugging techniques, debug and trace system 40 can capture trace information associated with operation of SoC 30, which can be analyzed by debugger 24. The trace information can include instruction information from various components of SoC 30, data information from various components of SoC 30, bus transaction information, and/or other information associated with operation of SoC 30. For example, in various implementations, debug and trace system 40 can observe software executing on processor 34 and processor 36, collecting trace information associated with the software execution. In FIG. 1, debug and trace system 40 can include various trace components, such as trace bus 44, a trace module for each processing element (such as a trace module 72a associated with processor 34 and a trace module 72b associated with processor 36), a system trace module 74, a trace buffer 76 for storing trace data, a trace port 78 for enabling debug host 20 to capture trace data, a serial wire output (SWO) 80. Each trace module (TM) can enables tracking and storing of real-time instruction flow, data flow, and/or program flow. Each trace module can be implemented as an embedded trace macrocell (ETM), a program trace macrocell (PTM), an instruction trace macrocell (ITM), or other suitable trace macrocell.

Turning to FIG. 3, FIG. 3 is a flowchart of exemplary method 100 that can be implemented for providing a non-debug domain system reset in a debug environment, such as that described with reference to FIG. 1 and FIG. 2, according to various aspects of the present disclosure. In various implementations, method 100 can be implemented by a system that includes a debug trigger interface and a reset control unit. At block 102, the debug trigger interface is connected to the reset control unit. In some implementations, a non-debug domain system reset request channel may be defined between a debug trigger interface and a reset control. At block 104, the debug trigger interface is configured to trigger the reset control unit to reset a non-debug domain. Additional steps can be provided before, during, and after method 100 and some of the steps described can be replaced or eliminated for other embodiments of method 100.

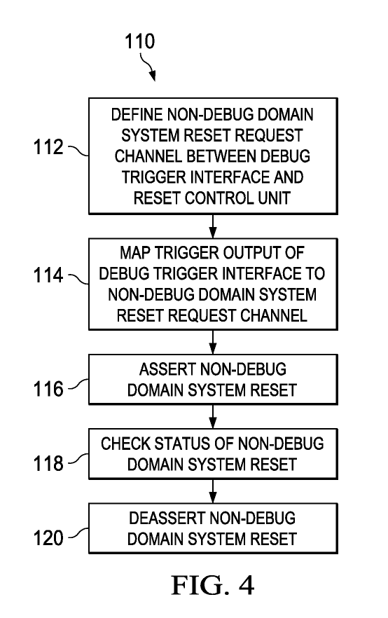

Turning to FIG. 4, FIG. 4 is a flowchart of an exemplary method 110 that can be implemented for providing a non-debug domain system reset in a debug environment, such as that described with reference to FIG. 1 and FIG. 2, according to various aspects of the present disclosure. In various implementations, method 110 can be implemented during operation of debug environment 10. For example, when debugger 24 connects (attaches) to SoC 30, debugger 24 can configure a debug domain of SoC 30 (such as initialize configuration settings for any accessible debug logic of SoC 30), and then implement method 110 to bring SoC 30 to a known state before performing a debug session, without affecting the debug domain of SoC 30, such as any initialized debug logic. Additional steps can be provided before, during, and after method 110 and some of the steps described can be replaced or eliminated for other embodiments of method 110.

At block 112, a non-debug domain system reset request channel is defined between a debug trigger interface and a reset control unit. For example, debugger 24 can assign a channel X of the SoC's debug trigger mechanism for non-debug domain system reset signaling. At block 114, a trigger output of the debug trigger interface is mapped to the non-debug domain system reset request channel. For example, debugger 24 can map trigger output N of system DTI 50 to channel X, which was assigned for non-debug domain system reset signaling (for example, DTIOUTNEN[N]==‘channel X enabled’). Method 110 can further include ensuring that a trigger input of the debug trigger interface used for monitoring a status of the non-debug domain system reset is not mapped to any channel. For example, debugger 24 can further ensure that trigger input M of system DTI 50, which is used for monitoring non-debug domain system reset status signaling from reset control unit 38, is not mapped to any channel.

At block 116, a non-debug domain system reset is asserted. For example, debugger 24 can assert a non-debug domain system reset by writing to DTI Application Trigger Set Register 62c, specifically the application trigger bit associated with channel X (for example, DTIAPPSET[X]==1). This causes a system reset channel event to be raised on channel X, which provides non-debug domain system reset request signaling to reset control unit 38. Reset control unit 38 can then initiate a non-debug domain system reset upon receiving the non-debug domain system reset request signaling, resetting the non-debug domain of SoC 30, except for the reset control unit 38 and the debug domain of SoC 30, including any debug logic that was initialized before initiating the non-debug domain system reset. In various implementations, before asserting the non-debug domain system reset, method 110 can include checking a non-debug domain system reset status to ensure that a non-debug domain system reset has not already been initiated. For example, debugger 24 can read DTI Trigger In Status Register 62f, specifically the trigger in status bit corresponding with trigger input M, to confirm that a non-debug domain system reset has not been asserted (for example, DTITRIGIN[M]==0).

At block 118, a status of the asserted non-debug domain system reset can be checked. For example, debugger 24 can read DTI Trigger In Status Register 62f, specifically the trigger in status bit corresponding with trigger input M, until it indicates that the non-debug domain system reset has been asserted (for example, DTITRIGIN[M]==1). At block 120, the non-debug domain system reset is deasserted. For example, once debugger 24 confirms that the non-debug domain system reset has been asserted (block 118), debugger 24 can clear the non-debug domain system reset request by writing to DTI Application Trigger Set Register 62c, specifically the application trigger bit associated with channel X can be set to a low state (for example, DTIAPPSET[X]==0). Alternatively, debugger 24 can write to DTI Application Trigger Clear Register 62d, specifically the application trigger bit associated with channel X (for example, DTIAPPCLEAR[X]==1), to deassert the system reset. In various implementations, method 110 can further include checking the non-debug domain system reset status to ensure that the non-debug domain system reset is no longer asserted. For example, debugger 24 can read DTI Trigger In Status Register 62f again, specifically the trigger in status bit corresponding with trigger input M, to ensure that the non-debug domain system reset has been deasserted (for example, DTITRIGIN[M]==0). Debugger 24 then knows that SoC 30 is in a known state, and debugger 24 can perform the debug session.

In various implementations, when implementing method 110, debugger 24 can use DTI Application Pulse Register (DTIAPPPULSE) 62e for asserting and deasserting non-debug domain system reset. For example, debugger 24 can assert a non-debug domain system reset (block 116) by setting the application pulse bit associated with channel X to a state that causes a system reset channel event pulse to be raised on channel X for a defined time. Since DTI Application Pulse Register 62e will automatically be cleared after the defined time, the non-debug domain system reset will automatically deassert without further action from debugger 24. In such implementations, debugger 24 can still check a status of the asserted non-debug domain system reset (block 118) by polling DTI Trigger In Status Register 62f, specifically the trigger in status bit corresponding with trigger input M, until it indicates that the non-debug domain system reset has been asserted.

In various implementations, components of target system are implemented in a same device. Alternatively, components of target system can be distributed in various integrated circuits and/or devices interconnected with each other, such that components of target system are integrated to provide a debug environment. In various implementations, the various circuits and/or components of the FIGURES can be implemented on a board of an associated electronic device. The board can be a general circuit board that can hold various components of an internal electronic system of the electronic device and, further, provide connectors for other peripherals. The board can provide the electrical connections by which the other components of the system can communicate electrically. Any suitable processors (inclusive of digital signal processors, microprocessors, supporting chipsets, etc.), memory elements, etc. can be suitably coupled to the board based on particular configuration needs, processing demands, computer designs, other considerations, or a combination thereof. Other components, such as external storage, sensors, controllers for audio/video display, and peripheral devices may be attached to the board as plug-in cards, via cables, or integrated into the board itself. In various implementations, the various circuits and/or components of the FIGURES can be implemented as stand-alone modules (for example, a device with associated components and circuitry configured to perform a specific application or function) or implemented as plug-in modules into application specific hardware of electronic devices. Note that particular embodiments of the present disclosure may be readily included in a system-on-chip (SOC) package, either in part, or in whole. An SOC represents an integrated circuit that integrates components of a computer or other electronic system into a single chip. It may contain digital, analog, mixed-signal, and often radio frequency functions: all of which may be provided on a single chip substrate. Other embodiments may include a multi-chip-module (MCM), with a plurality of separate ICs located within a single electronic package and configured to interact closely with each other through the electronic package. In various other embodiments, the various functions described herein may be implemented in one or more semiconductor cores (such as silicon cores) in application specific integrated circuits (ASICs), field programmable gate arrays (FPGAs), other semiconductor chips, or combinations thereof.

The various functions outlined herein may be implemented by logic encoded in one or more non-transitory and/or tangible media (for example, embedded logic provided in an application specific integrated circuit (ASIC), as digital signal processor (DSP) instructions, software (potentially inclusive of object code and source code) to be executed by a processor, or other similar machine, etc.). In some of these instances, a memory element can store data used for the operations described herein. This includes the memory element being able to store logic (for example, software, code, processor instructions) that is executed by a processor to carry out the activities described herein. The processor can execute any type of instructions associated with the data to achieve the operations detailed herein. In various implementations, the processor can transform an element or an article (such as data) from one state or thing to another state or thing. In another example, the activities outlined herein may be implemented with fixed logic or programmable logic (such as software/computer instructions executed by the processor) and the elements identified herein can be some type of a programmable processor (such as a DSP), programmable digital logic (e.g., a FPGA, an erasable programmable read only memory (EPROM), an electrically erasable programmable ROM (EEPROM)), or an ASIC that includes digital logic, software, code, electronic instructions, or any suitable combination thereof.

Note that the activities discussed above with reference to the FIGURES are applicable to any integrated circuits that involve signal processing, particularly those that can execute specialized software programs or algorithms, some of which may be associated with processing digitized real-time data. Certain embodiments can relate to multi-DSP signal processing, floating point processing, signal/control processing, fixed-function processing, microcontroller applications, etc. In certain contexts, the features discussed herein can be applicable to medical systems, scientific instrumentation, wireless and wired communications, radar, industrial process control, audio and video equipment, current sensing, instrumentation (which can be highly precise), and other digital-processing-based systems. Moreover, certain embodiments discussed above can be provisioned in digital signal processing technologies for medical imaging, patient monitoring, medical instrumentation, and home healthcare. This could include pulmonary monitors, accelerometers, heart rate monitors, pacemakers, etc. Other applications can involve automotive technologies for safety systems (e.g., stability control systems, driver assistance systems, braking systems, infotainment and interior applications of any kind) Furthermore, powertrain systems (for example, in hybrid and electric vehicles) can use high-precision data conversion products in battery monitoring, control systems, reporting controls, maintenance activities, etc. In yet other example scenarios, the teachings of the present disclosure can be applicable in the industrial markets that include process control systems that help drive productivity, energy efficiency, and reliability. In consumer applications, the teachings of the signal processing circuits discussed above can be used for image processing, auto focus, and image stabilization (e.g., for digital still cameras, camcorders, etc.). Other consumer applications can include audio and video processors for home theater systems, DVD recorders, and high-definition televisions. Yet other consumer applications can involve advanced touch screen controllers (e.g., for any type of portable media device). Hence, such technologies could readily be a part of smartphones, tablets, security systems, PCs, gaming technologies, virtual reality, simulation training, etc.

The specifications, dimensions, and relationships outlined herein have only been offered for purposes of example and teaching only. Each of these may be varied considerably without departing from the spirit of the present disclosure, or the scope of the appended claims. The specifications apply only to non-limiting examples and, accordingly, they should be construed as such. In the foregoing description, example embodiments have been described with reference to particular processor and/or component arrangements. Various modifications and changes may be made to such embodiments without departing from the scope of the appended claims. The description and drawings are, accordingly, to be regarded in an illustrative rather than a restrictive sense.

Note that with the numerous examples provided herein, interaction may be described in terms of two, three, four, or more processing components. However, this has been done for purposes of clarity and example only. It should be appreciated that the system can be consolidated in any suitable manner. Along similar design alternatives, any of the illustrated components, modules, circuits, and elements of the FIGURES may be combined in various possible configurations, all of which are clearly within the broad scope of this Specification. In certain cases, it may be easier to describe one or more of the functionalities of a given set of flows by only referencing a limited number of processing components. It should be appreciated that the processing components of the FIGURES and its teachings are readily scalable and can accommodate a large number of components, as well as more complicated/sophisticated arrangements and configurations. Accordingly, the examples provided should not limit the scope or inhibit the broad teachings of the processing system and/or components as potentially applied to a myriad of other architectures.

Further, note that references to various features (e.g., elements, structures, modules, components, steps, operations, characteristics, etc.) included in “one embodiment”, “example embodiment”, “an embodiment”, “another embodiment”, “some embodiments”, “various embodiments”, “other embodiments”, “alternative embodiment”, and the like are intended to mean that any such features are included in one or more embodiments of the present disclosure, but may or may not necessarily be combined in the same embodiments. It is further noted that “coupled to” and “coupled with” are used interchangeably herein, and that references to a feature “coupled to” or “coupled with” another feature include any communicative coupling means, electrical coupling means, mechanical coupling means, other coupling means, or a combination thereof that facilitates the feature functionalities and operations, such as the security check mechanisms, described herein.

Numerous other changes, substitutions, variations, alterations, and modifications may be ascertained to one skilled in the art and it is intended that the present disclosure encompass all such changes, substitutions, variations, alterations, and modifications as falling within the scope of the appended claims. In order to assist the United States Patent and Trademark Office (USPTO) and, additionally, any readers of any patent issued on this application in interpreting the claims appended hereto, Applicant wishes to note that the Applicant: (a) does not intend any of the appended claims to invoke paragraph six (6) of 35 U.S.C. section 112 as it exists on the date of the filing hereof unless the words “means for” or “steps for” are specifically used in the particular claims; and (b) does not intend, by any statement in the specification, to limit this disclosure in any way that is not otherwise reflected in the appended claims.

### OTHER NOTES, EXAMPLES, AND IMPLEMENTATIONS

A system is provided that can include means for issuing a non-debug domain system reset request from the debug trigger interface to the reset control unit, such that the debug trigger interface triggers the reset control unit to reset a non-debug domain. In various implementations, a system can include means for defining a non-debug domain system reset request channel between a debug trigger interface and a reset control unit, means for configuring the debug trigger interface to trigger the reset control unit to reset the non-debug domain, and/or means for monitoring a status of the non-debug domain system reset. The ‘means for’ in these instances can include (but is not limited to) using any suitable component discussed herein, along with any suitable software, circuitry, hub, computer code, logic, algorithms, hardware, controller, interface, link, bus, communication pathway, etc. In various implementations, the system includes memory that includes instructions that when executed cause the system to perform any of the activities discussed herein.

What is claimed is:

1. A system-on-chip comprising:
a reset control unit configured to reset a non-debug domain; and
a debug domain that includes a debug trigger interface connected to the reset control unit, wherein the debug trigger interface is configured to trigger the reset control unit to reset the non-debug domain.

2. The system-on-chip of claim 1, wherein the debug trigger interface has a trigger output connected to a non-debug domain system reset request of the reset control unit.

3. The system-on-chip of claim 2, wherein the trigger output is connected to the non-debug domain system reset request via an inverter.

4. The system-on-chip of claim 1, wherein the debug trigger interface is further configured to monitor a status of the non-debug domain system reset.

5. The system-on-chip of claim 4, wherein the debug trigger interface has a trigger input connected to a non-debug domain system reset status of the reset control unit.

6. The system-on-chip of claim 5, wherein the trigger input is connected to the non-debug domain system reset status via an inverter.

7. The system-on-chip of claim 1, wherein the debug trigger interface includes an application trigger register configured to cause the debug trigger interface to issue a non-debug domain system reset request to the reset control unit.

8. The system-on-chip of claim 1, wherein the debug trigger interface includes an application trigger in status register configured to indicate a status of the non-debug domain system reset received from the reset control unit.

9. The system-on-chip of claim 1, wherein the debug trigger interface includes an application pulse register configured to cause the debug trigger interface to issue a non-debug domain system reset request to the reset control unit for a defined time.

10. A method for enabling a non-debug domain system reset of a system, wherein the system includes a debug trigger interface connected to a reset control unit, the method comprising:
issuing a non-debug domain system reset request from the debug trigger interface to the reset control unit, such that the debug trigger interface triggers the reset control unit to reset a non-debug domain of the system.

11. The method of claim 10, wherein the non-debug domain system reset request is issued from a trigger output of the debug trigger interface connected to a non-debug domain system reset request of the reset control unit.

12. The method of claim 11, further comprising inverting the non-debug domain system reset request issued to the reset control unit.

13. The method of claim 10, wherein the debug trigger interface includes an application trigger register, and the debug trigger interface issues the non-debug domain system based on a state of the application trigger register.

14. The method of claim 10, further comprising monitoring, by the debug trigger interface, a non-debug domain system reset status.

15. The method of claim 14, wherein the monitoring includes observing a status of a trigger input of the debug trigger interface connected to a non-debug domain system reset status of the reset control unit.

16. The method of claim 15, further comprising inverting a non-debug domain system reset status signal received by the trigger input from the reset control unit.

17. The method of claim 14, wherein the debug trigger interface includes an application trigger in status register, and the debug trigger interface sets a state of the application trigger in status register based on a non-debug domain system reset status received from the reset control unit.

18. A non-transitory media encoded with logic that includes code for execution and, when executed by a processor, operable to perform operations comprising:
defining a non-debug domain system reset request channel between a debug trigger interface and a reset control unit; and
configuring the debug trigger interface to trigger the reset control unit to reset the non-debug domain.

19. The non-transitory media of claim 18, the operations further comprising monitoring a status of the non-debug domain system reset.

20. The non-transitory media of claim 19, the operations further comprising:
setting a state of an application trigger register to cause the debug trigger interface to issue a non-debug domain system reset request to the reset control unit; and
polling a state of an application trigger in status register, wherein the state of the application trigger in register is based on a non-debug domain system reset status received from the reset control unit.
